(19) United States
(12) Patent Application Publication
(10) Pub. No.: US 2010/0314639 A1
(43) Pub. Date: Dec. 16, 2010

(54) LIGHT EMITTING DEVICE AND DISPLAY DEVICE USING THE SAME

(75) Inventors: Reiko Taniguchi, Osaka (JP); Masayuki Ono, Osaka (JP); Eiichi Satoh, Osaka (JP); Takayuki Shimamura, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Kadoma-shi, Osaka (JP)

(21) Appl. No.: 12/918,733

(22) PCT Filed: Feb. 19, 2009
(86) PCT No.: PCT/JP2009/000716

§ 371 Date: Aug. 20, 2010

(30) Foreign Application Priority Data
Feb. 21, 2008 (JP) 2008-040327
Feb. 21, 2008 (JP) 2008-040328
Feb. 21, 2008 (JP) 2008-040331

(51) Int. Cl. H01L 33/02; H01L 33/26; H01L 33/44; H01L 33/50

(52) U.S. Cl. 257/89; 257/98; 257/103; 257/E33.061; 257/E33.067; 257/E33.013; 257/E33.005

(57) ABSTRACT

The light emitting device (10) of the present invention is provided with a light emitting layer (13), and a pair of electrodes (12 and 14) for injecting electric current into the light emitting layer (13). The light emitting layer (13) includes GaN-based semiconductor particles (21). The light emitting device (10) of the present invention is provided further with a light absorber for absorbing at least part of the light with a wavelength of 470 nm to 800 nm. The light absorber is, for example, a light absorption film (19) provided on at least a part of the surface of each of the GaN-based semiconductor particles (18). Further, the light absorber may be light absorption particles dispersed in the light emitting layer, or may be a light absorption layer disposed on the light exit side with respect to the light emitting layer.

### TECHNICAL FIELD

The present invention relates to a light emitting device using a GaN-based semiconductor and a display device using the light emitting device.

### BACKGROUND ART

GaN-based semiconductors have excellent properties as a light emitting material, and LEDs (Light emitting diode) using a single crystal thin film of the GaN-based semiconductors have been put to practical use as a direct current-light emitting device with low voltage and high brightness. It should be noted that the light emitting devices using the GaN-based semiconductors generally emit blue light.

The light emitting devices using such GaN-based semiconductors are used as a display and the like. For example, JP 3397141 B2 discloses a white LED using a GaN-based semiconductor for use as a white light source of a display. In this white LED, a GaInN-based blue light emitting device is used, and part of the blue light emitted from the blue light emitting device is converted into yellow by a GaN substrate, which constitutes the blue light emitting device, doped with the fluorescent center. That is, the white LED achieves white light by mixing blue and yellow.

On the other hand, various techniques for achieving full color displays using a monochrome light emitting device have been studied. In organic EL (Electro Luminescence) displays, various full color systems have been proposed. For example, JP 3369618 B2 discloses an organic EL display that achieves full color displays by converting blue light emitted from a light emitting layer into green light or red light using a color conversion layer (fluorescent medium) formed of a fluorescent material to produce RGB pixels.

The inventors have found that a light emitting device capable of emitting light with high brightness under a low direct current can be achieved by using a particulate GaN-based semiconductor (GaN-based semiconductor particles). Then, the inventors made efforts to achieve an RGB (R: red, G: green, and B: blue) full color light emitting device using the GaN-based semiconductor particles.

FIG. 5 is a schematic sectional view showing an RGB full color light emitting device in which a full color system as disclosed JP 3369618 B2 is applied to a light emitting device that uses the GaN-based semiconductor particles. The RGB full color light emitting device 100 is formed by disposing a back electrode 102, a light emitting layer 103 and a transparent electrode 104 on a substrate 101 in this order and further providing a color conversion layer (a layer 105a for conversion into red light, and a layer 105b for conversion into green light) on the transparent electrode 104. In the figure, 106 denotes a black matrix. The light emitting layer 103 includes GaN-based semiconductor particles 201. The GaN-based semiconductor particles 201 are dispersed in the light emitting layer 103, for example, in contact with the back electrode 102 and the transparent electrode 104 so that the electric current injected into the light emitting layer 103 by the back electrode 102 and the transparent electrode 104 can be injected efficiently into the GaN-based semiconductor particles 201. Further, the back electrode 102 is connected electrically to the transparent electrode 104 via a direct current power source 107. Upon application of a voltage using the direct current power source 107 in the light emitting device 100, holes are injected into the light emitting layer 103 from the back electrode 102 that is connected to the positive electrode, and electrons are injected into the light emitting layer 103 from the transparent electrode 104 that is connected to the negative electrode. The electrons and the holes that have been injected into the light emitting layer 103 are injected into the GaN-based semiconductor particles 201 to recombine inside the particles 201. Thus, light emission occurs. This light exits the light emitting device 100 as each part of RGB light by transmitting through the transparent electrode 104 and the color conversion layers 105a and 105b.

However, the light emitting device with the above-mentioned configuration suffers from a problem that each color of the RGB light to exit has poor color purity. It should be noted that the arrows X₁ to X₃ each denote light emitting components having other colors than R, G, and B colors in the figures.

### DISCLOSURE OF THE INVENTION

It is an object of the present invention to provide a light emitting device capable of emitting light with high brightness under a low voltage direct current as well as emitting blue light with high color purity, and further capable of allowing the RGB light with high color purity to be obtained when a full color system is applied. Further, another object of the present invention is to provide a display device using such a light emitting device.

The inventors have found that the phenomenon in which the color purity of each part of the RGB light decreases in a light emitting device that uses GaN-based semiconductor particles is because light components of other colors, that is, the light components with a wavelength of 470 nm to 800 nm are included in the emitted blue light due to factors such as defects in the surface of the GaN-based semiconductor particles.

Therefore, a light emitting device provided with a light emitting layer including GaN-based semiconductor particles, a pair of electrodes for injecting electric current into the light emitting layer, and a light absorber for absorbing at least part of the light with a wavelength of 470 nm to 800 nm is provided as a first light emitting device of the present invention.

Further, there is provided a light emitting device, as a second light emitting device of the present invention, provided with a light emitting layer, and a pair of electrodes for injecting electric current into the light emitting layer. The light emitting layer includes GaN-based semiconductor particles, and at least a part of the surface of each of the GaN-based semiconductor particles is provided with a light absorption film for absorbing at least part of the light with a wavelength of 470 nm to 800 nm.

Further, there is provided a light emitting device, as a third light emitting device of the present invention, provided with a light emitting layer, and a pair of electrodes for injecting electric current into the light emitting layer. The light emitting layer includes GaN-based semiconductor particles and light absorption particles for absorbing at least part of the light with a wavelength of 470 nm to 800 nm. The GaN-based semiconductor particles and the light absorption particles are dispersed in the light emitting layer.

Further, there is provided a light emitting device, as a fourth light emitting device of the present invention, provided with a light emitting layer, and a pair of electrodes for injecting electric current into the light emitting layer. The light emitting layer includes GaN-based semiconductor particles, and the light emitting device is provided further with a light absorption layer for absorbing at least part of the light with a wavelength of 470 nm to 800 nm. The light absorption layer is disposed on a light exit side with respect to the light emitting layer.

The present invention provides also a display device provided with the above-mentioned second, third or fourth light emitting device of the present invention.

The light emitting devices of the present invention can remove at least part of the light with a wavelength of 470 nm to 800 nm that is included in the light emitted from GaN-based semiconductor particles, using a light absorber, a light absorption film, light absorption particles or a light absorption layer. In this way, the light absorber, the light absorption film, the light absorption particles or the light absorption layer can prevent the exit of the light components with a wavelength of 470 nm to 800 nm, so that it is possible to achieve the emission of blue light with higher color purity than in conventional devices. Further, the emission of blue light with high color purity is possible, thus allowing the RGB light with high color purity to be obtained when a full color system in which blue light is converted into other colors (red and green) is applied. This enables a full color display with high color reproducibility to be achieved. Further, the light emitting device of the present invention uses GaN-based semiconductor particles, and therefore is capable of emitting light with high brightness under a low direct current.

### BRIEF DESCRIPTION OF THE DRAWINGS

FIG. 1 is a sectional view illustrating a configuration example of a light emitting device according to Embodiment 1 of the present invention.

FIG. 2 is a sectional view illustrating a configuration example of a light emitting device according to Embodiment 2 of the present invention.

FIG. 3 is a sectional view illustrating a configuration example of a light emitting device according to Embodiment 3 of the present invention.

FIG. 4 is a sectional view illustrating a configuration example of a light emitting device according to Embodiment 4 of the present invention.

FIG. 5 is a sectional view illustrating a configuration example of a conventional light emitting device.

### BEST MODE FOR CARRYING OUT THE INVENTION

Hereinafter, embodiments for carrying out the present invention are described with reference to the figures. In some of the figures referenced in the description below, hatching may be omitted so that the figures can be viewed easily. Further, the configurations of the light emitting device described in the following are to be considered as an example of the present invention, and the light emitting device of the present invention is not limited to the following configurations.

### Embodiment 1

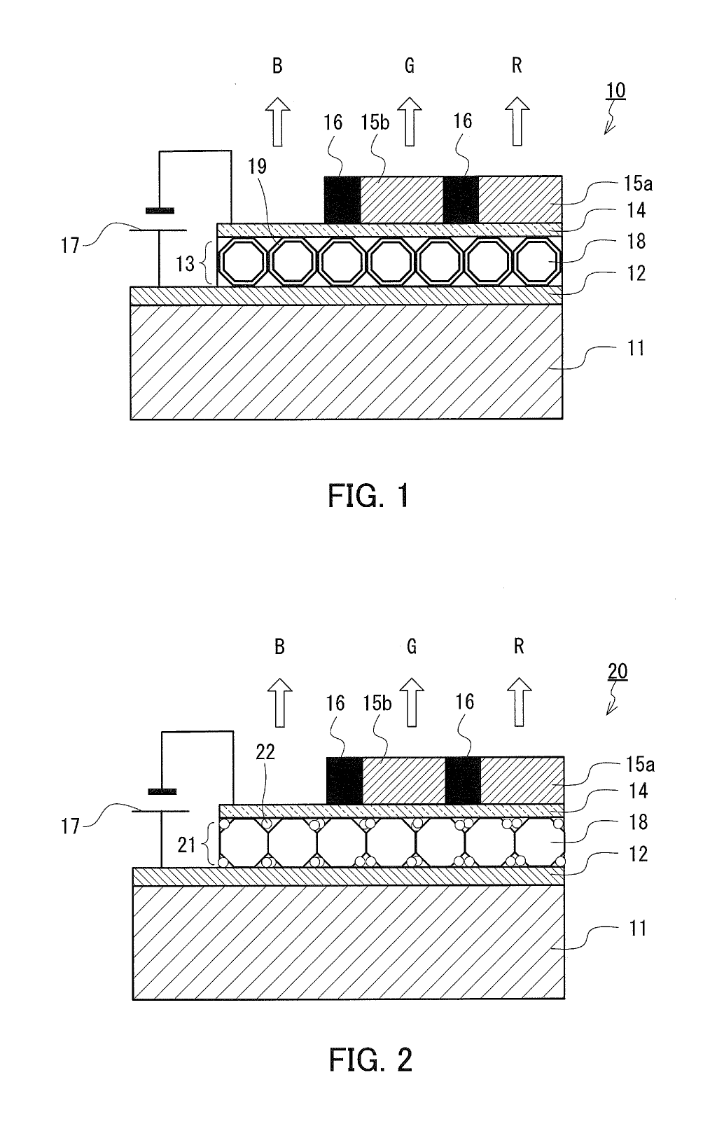

As a light emitting device according to Embodiment 1 of the present invention, an RGB full color light emitting device that employs a full color system is described. FIG. 1 is a sectional view illustrating a schematic configuration example of the light emitting device according to this embodiment. A light emitting device 10 is provided with a back electrode 12, a light emitting layer 13 and a transparent electrode 14 on a substrate 11. Further, the light emitting device 10 is provided with color conversion layers 15a and 15b disposed on the transparent electrode 14 as a configuration for achieving a full color system. The color conversion layer 15a serves to convert blue light into red light. The color conversion layer 15b serves to convert blue light into green light. Since the light emitted from the light emitting layer 13 can be used for blue light as it is, there is no need for a color conversion layer. Further, in order to prevent colors from being mixed with each other, a black matrix 16 is disposed between each color in this embodiment. The back electrode 12 is connected electrically to the transparent electrode 14 via a direct current power source 17. That is, the light emitting device 10 is formed by disposing the light emitting layer 13 between the back electrode 12 and the transparent electrode 14 that serve as a pair of electrodes to inject electric current into the light emitting layer 13.

The light emitting layer 13 includes GaN-based semiconductor particles 18, and the surface of each GaN-based semiconductor particle 18 is covered by a light absorption film (light absorber) 19 that absorbs at least part of light with a wavelength of 470 nm to 800 nm. It should be noted that although the light absorption film 19 is provided so as to cover the entire surface of the GaN-based semiconductor particle 18 in this embodiment, as indicated in FIG. 1, the light absorption film 19 only needs to be provided on at least a part of the surface of the GaN-based semiconductor particle 18.

In the light emitting device 10, when a voltage is applied using the direct current power source 17, holes are injected into the light emitting layer 13 from the back electrode 12 that is connected to the positive electrode, and electrons are injected into the light emitting layer 13 from the transparent electrode 14 that is connected to the negative electrode. The electrons and the holes that have been injected into the light emitting layer 13 are injected into the GaN-based semiconductor particles 18 to recombine inside the particles 18. This recombination causes light emission. When the emitted light passes through the light absorption film 19, at least part of the light with a wavelength of 470 nm to 800 nm is absorbed by the light absorption film 19. Accordingly, the light to exit from the light emitting layer 13 is blue light with high color purity after the removal of the light by the light absorption film 19. The light that has exited from the light emitting layer 13 transmits through the transparent electrode 14 and the color conversion layers 15a and 15b, so as to exit the light emitting device 10. The blue light is converted into red light or green light by the color conversion layers 15a and 15b, so that light of each of the RGB colors can be obtained.

It should be noted that a color filter may be provided over the color conversion layers 15a and 15b for the purpose of further improving the color purity. Further, a protective film may be provided on the color conversion layers 15a and 15b, or on the color filter in the case of providing the color filter, for the purpose of preventing the deterioration of the device.

Further, although the black matrix 16 is provided to prevent colors from being mixed with each other in this embodiment, it also is possible to employ other configurations, for example, in which a separator is provided inside the light emitting layer 13 for each color pixel, or in which, in the case where a color filter is provided, a black matrix is provided for each color pixel of the color filter.

Hereinafter, each component of the light emitting device 10 is described in detail.

<Substrate>

A substrate capable of supporting layers to be formed thereon is used for the substrate 11. Specifically, ceramic substrates, such as silicon, Al₂O₃, and AlN, and plastic substrates, such as polyester, and polyimide, can be used therefor. Further, glass substrates (for example, “Corning 1737” manufactured by Corning Incorporated) and quartz substrates also can be used. It also is possible to use an alkali-free glass substrate or a soda lime glass substrate the surface of which is coated with alumina or the like as an ion barrier layer, so that alkali ions, etc. that are generally contained in glass should not affect the light emitting device. It should be noted that these descriptions are indicated as an example, and the material of the substrate 11 is not particularly limited thereto.

<Electrode>

The material of the electrode disposed on the side where the light does not exit (the back electrode 12 in this embodiment) is not particularly limited as long as it is an electrically conductive material that is used generally for an electrode. For example, a thin film of metals such as Au, Ag, Al, Cu, Ta, Ti and Pt can be used. Further, it also is possible to use a multilayer conductive film in which a plurality of such thin films of metal are stacked.

The material of the electrode disposed on the side where the light exits (the transparent electrode 14 in this embodiment) is not particularly limited as long as it is transparent to the wavelength of the light to be emitted from the GaN-based semiconductor particles 18, and it desirably has a low resistivity. Preferred examples of the material of the transparent electrode 14 include: metal oxides such as ITO (In₂O₃ doped with SnO₂, also referred to as indium tin oxide), ZnO, AlZnO and GaZnO; and electrically conductive polymers such as polyaniline, polypyrrole, PEDOT/PSS (Poly(3,4-ethylnedioxythiophene)/Poly(styrene sulfonate)) and polythiophene. However, the material of the transparent electrode 14 is not particularly limited thereto.

For example, methods such as, sputtering, electron beam evaporation, and ion plating can be used suitably for depositing an ITO film, for the purpose of improving the transparency, or decreasing the resistivity. Moreover, the deposited film may be subjected to a surface treatment, such as a plasma treatment, for controlling the resistivity. The film thickness of the transparent electrode 14 can be determined in accordance with required values for the sheet resistance and the visible light transmittance.

The electrodes 12 and 14 may be formed so as to cover the entire surface inside the layer, or may be constituted by a plurality of stripe-shaped electrodes. Further, in the case where the back electrode 12 and the transparent electrode 14 each are constituted by a plurality of the stripe-shaped electrodes, it also is possible to employ a configuration in which the stripe-shaped electrodes constituting the back electrode 12 are in a skewed relationship to the stripe-shaped electrodes constituting the transparent electrode 14, and the projection of each stripe-shaped electrode constituting the back electrode 12 and the projection of each stripe-shaped electrode constituting the transparent electrode 14 on the light emitting surface (surface parallel to the light emitting layer 13) are crossed with each other. In this case, light emission at a specific point is possible in the light emitting device by applying a voltage to each electrode selected respectively from the stripe-shaped electrodes of the back electrodes 12 and the stripe-shaped electrodes of the transparent electrodes 14, which enables the light emitting device to be used as a display device.

<Color Conversion Layers>

The color conversion layers 15a and 15b are provided in the light emitting device 10 of this embodiment for achieving a full color system. The color conversion layer 15a contains a fluorescent material capable of converting blue light into red light, and the color conversion layer 15b contains a fluorescent material capable of converting blue light into green light. These fluorescent materials may be an inorganic material or an organic material. Specifically, a fluorescent material capable, for example, of absorbing blue light at a wavelength of 470 nm or less and generating fluorescence at a wavelength of 500 nm to 550 nm can be used for the color conversion layer 15b, and a fluorescent material capable, for example, of absorbing blue light at a wavelength of 470 nm or less and generating fluorescence at a wavelength of 700 nm to 800 nm can be used for the color conversion layer 15a. Examples of the fluorescent material to be used for blue-to-green conversion include inorganic phosphors such as SrGa₂S₄:Eu, and organic fluorescent dyes such as coumarin-based dyes. Examples of the fluorescent material to be used for blue-to-red conversion include inorganic phosphors such as SrS:Eu, and CaS:Eu, and organic fluorescent dyes such as rhodamine-based dyes and oxazine-based dyes.

The color conversion layers 15a and 15b can be formed by various methods such as evaporation, printing, and dispersion methods. In the dispersion method, a photoresist that contains a fluorescent material dispersed therein is disposed, which is subjected to patterning by photolithography and the like. Such a resist contains, for example, a binder resin, a solvent and a curing accelerator.

<Light Emitting Layer>

The light emitting layer 13 at least includes the GaN-based semiconductor particles 18 that serve as a luminescent material. The light emitting layer 13 further may include a binder resin that allows the GaN-based semiconductor particles 18 to be dispersed therein, and a material intended to improve the injection performance of electrons or holes into the GaN-based semiconductor particles 18 (such as a hole transport material, an electron transport material, and the like).

Examples of the inorganic hole transport material as an inorganic material with p-type conductivity include: semimetal semiconductors such as Si, Ge, SiC, Se, SeTe, and As₂Se₃; binary compound semiconductors such as ZnSe, CdS, ZnO, and CuI; chalcopyrite semiconductors, such as CuGaS₂, CuGaSe₂, and CuInSe₂, and mixed crystals of these; and oxide semiconductors such as CuAlO₂, and CuGaO₂, and mixed crystals of these. Further, examples of the organic hole transport material include benzidine derivatives, phthalocyanine derivatives, tetraphenyl butadiene derivatives, triphenyl amine derivatives, and diamine derivatives. ITO, metal complexes such as Alq₃, phenanthroline derivatives, and silole derivatives can be mentioned as the electron transport material.

<GaN-Based Semiconductor Particles>

The structure of the GaN-based semiconductor particles 18 in the light emitting layer 13 is not particularly limited, and a column structure, or a quantum dot structure may be employed. The size of each GaN-based semiconductor particles is not particularly limited, but it is desirably at least 0.5 μm. Generally, there exist many surface levels that are a cause of non-radiative recombination on the surface of the semiconductor particles, and therefore, a smaller surface area of the particles is desirable in order to obtain high luminescence efficiency. Accordingly, the average particle size of the GaN-based semiconductor particles 18 is desirably at least 0.5 μm in this embodiment so that high luminescence efficiency can be obtained by preventing the increase in the surface area. Further, in view of the application to displays, it is desirable that at least several or more of the GaN-based semiconductor particles 18 be included per pixel (about 300 μm square) to achieve an image display of uniform quality. Accordingly, the average particle size of the GaN-based semiconductor particles 18 is desirably 50 μm or less. The particle size herein means an equivalent light scattering diameter as measured by a laser diffraction scattering, and the average particle size means a particle size at which the cumulative percentage in the particle size-number distribution reaches 50%.

A GaN-based semiconductor is a semiconductor containing a gallium (Ga) atom among group III nitride semiconductors. Specifically, examples of the GaN-based semiconductor include gallium nitride (GaN), indium-gallium nitride mixed crystal (InGaN), aluminum-gallium nitride mixed crystal (AlGaN), and indium-aluminum-gallium nitride mixed crystal (InAlGaN). Such GaN-based semiconductor particles 18 may be doped with at least one element selected from group 16 elements and group 14 elements such as O, S, Se, Te, Si, Ge and Sn, or may be doped with at least one element selected from group 12 elements and group 2 elements such as Zn, Cd, Mg, Be and Ca.

Furthermore, the above-mentioned GaN-based semiconductor particles 18 may be doped with one or several kinds of impurity elements that serve as a donor or acceptor. Further, the GaN-based semiconductor particles 18 may have a structure in which p-type and n-type are mixed, or may have a p-i-n quantum well structure.

<Light Absorption Film>

The light absorption film 19 absorbs at least part of the light with a wavelength of 470 nm to 800 nm, and absorbs at least light with a certain wavelength included in this wavelength range. The light absorption film 19 preferably absorbs at least part of the light with a wavelength of 550 nm to 650 nm. The light absorption film 19 removes at least part of the light with a wavelength of 470 nm to 800 nm that is included in the light emitted from the GaN-based semiconductor particles 18 and that causes a reduction in the color purity, thereby increasing the purity of blue light to exit from the light emitting layer 13. Furthermore, it is possible to ensure a higher purity of blue light by removing at least part of the light with a wavelength of 550 nm to 650 nm that is the wavelength range of yellow to orange light. In order to achieve still higher color purity, the light absorption film 19 preferably absorbs all the light in the wavelength range of 550 nm to 650 nm, and more preferably absorbs all the light in the wavelength range of 470 nm to 800 nm. Further, it is preferable to provide the light absorption film 19 so that the transmittance (transmitted light/incident light) with respect to the light with a wavelength of 550 nm to 650 nm is 0.3 or less in the light emitting layer 13. With this light absorption film 19, still higher color purity can be achieved by effectively removing yellow to orange light that is included in the light emitted from the GaN-based semiconductor particles 18. It should be noted that since the light emitting device 10 in this embodiment is intended to obtain blue light, the light absorption film 19 does not absorb blue light substantially, and even if absorbing it, the absorptivity is very low.

The light absorption film 19 is formed using a material capable of absorbing the light in the above-mentioned wavelength range. For example, an iron blue pigment that is cobalt-aluminum-silicon oxide, ultramarine that is a silicate of aluminum and sodium, inorganic pigments such as cobalt aluminate, organic pigments such as copper phthalocyanine and indanthrone blue, nanoparticles of metals such as gold and silver, and semiconductor materials with a band gap of about 1.7 to 2.5 eV (for example, SiC, Se, AlP, AlAs, GaP, ZnSe, ZnTe, CdS, and CdSe) can be used for the formation. The light absorption film 19 may include only one kind of material, or may include two or more kinds of materials. Further, it also is possible to produce the light absorption film 19 using a multilayer interference film such as a silicon oxide/chromium-based film and a silicon oxide/titanium-based film.

The cover structure of the light absorption film 19 with respect to the GaN-based semiconductor particle 18 is not particularly limited. The light absorption film 19 may be formed as a continuous film, or may have an island structure. Further, the surface coverage of the GaN-based semiconductor particle 18 by the light absorption film 19 is preferably 70% or more. The surface coverage of 70% or more enables unnecessary light components to be removed more effectively.

Further, the light absorption film 19 desirably is formed using a material that has an electrical conductivity. This is because electrons and holes can be injected efficiently into the GaN-based semiconductor particles 18 even when the surface coverage of the GaN-based semiconductor particles 18 by the light absorption film 19 is high. In this regard, a material with low electrical resistivity such as metal nanoparticles preferably is used for forming the light absorption film 19. Further, a material with high electrical resistivity also can be used when the electrical conductivity can be ensured by reducing the thickness of the light absorption film 19.

The thickness of the light absorption film 19 varies depending on the material, and thus is not particularly limited. However, it is preferably 1 μm or less for the reason of the electrical conductivity.

The light absorption film 19 can be produced using methods such as electron beam evaporation and vacuum evaporation.

### Embodiment 2

As a light emitting device according to Embodiment 2 of the present invention, an RGB full color light emitting device that employs a full color system is described. It should be noted that in this embodiment, the same parts as in the light emitting device of Embodiment 1 may be indicated with identical reference numerals and the same description is not repeated in some cases.

FIG. 2 is a sectional view illustrating a schematic configuration example of the light emitting device according to this embodiment. The light emitting device of this embodiment has the same configurations as the light emitting device of Embodiment 1 except for the configuration of the light emitting layer. Therefore, only the light emitting layer is described herein.

A light emitting layer 21 in a light emitting device 20 indicated in FIG. 2 includes the GaN-based semiconductor particles 18 and light absorption particles (light absorber) 22. The light absorption particles 22 absorb at least part of the light with a wavelength of 470 nm to 800 nm.

In the light emitting device 20, when a voltage is applied using the direct current power source 17, holes are injected into the light emitting layer 21 from the back electrode 12 that is connected to the positive electrode, and electrons are injected into the light emitting layer 21 from the transparent electrode 14 that is connected to the negative electrode. The electrons and the holes that have been injected into the light emitting layer 21 are injected into the GaN-based semiconductor particles 18 to recombine inside the particles 18. This recombination causes light emission. Among the light emitted from the GaN-based semiconductor particles 18, at least part of the light with a wavelength of 470 nm to 800 nm is absorbed by the light absorption particles 22. Accordingly, the light to exit from the light emitting layer 21 is allowed to be blue light with high color purity after the removal of the light by the light absorption particles 22. The light that has exited from the light emitting layer 21 transmits through the transparent electrode 14 and the color conversion layers 15a and 15b, so as to exit the light emitting device 20. The blue light is converted into red light or green light by passing through the color conversion layers 15a and 15b, so that light of each part of the RGB colors can be obtained.

It should be noted that a color filter may be provided over the color conversion layers 15a and 15b for the purpose of further improving the color purity, as is the case of Embodiment 1. Further, a protective film may be provided on the color conversion layers 15a and 15b, or on the color filter in the case of providing the color filter, for the purpose of preventing the deterioration of the device.

Further, although the black matrix 16 is provided to prevent colors from being mixed with each other in this embodiment, it also is possible to employ other configurations, for example, in which a separator is provided inside the light emitting layer 21 for each color pixel, or in which, in the case where a color filter is provided, a black matrix is provided for each color pixel of the color filter.

The components of the substrate 11, the electrodes (back electrode 12 and transparent electrode 14), the color conversion layers 15a and 15b and the GaN-based semiconductor particles 18 of the light emitting layer 21 in the light emitting device 20 respectively are the same as those in Embodiment 1, and thus the descriptions thereof are omitted in this embodiment.

<Light Emitting Layer>

The light emitting layer 21 includes the GaN-based semiconductor particles 18 that serve as a luminescent material and the light absorption particles 22 capable of absorbing at least part of the light with a wavelength of 470 nm to 800 nm. The light emitting layer 13 may further include a binder resin that allows the GaN-based semiconductor particles 18 and the light absorption particles 22 to be dispersed therein, and a material intended to improve the injection performance of electrons or holes into the GaN-based semiconductor particles 18 (such as a hole transport material, an electron transport material, and the like). The specific examples of the hole transport material and the electron transport material are as described in Embodiment 1.

There is no particular limitation on the method for producing the light emitting layer 21 that includes the GaN-based semiconductor particles 18 and the light absorption particles 22. For example, the light emitting layer 21 can be produced by applying, onto the back electrode 12, a paste that has been prepared by mixing the GaN-based semiconductor particles 18 and the light absorption particles 22 in a binder resin.

<Light Absorption Particles>

The light absorption particles 22 absorb at least part of the light with a wavelength of 470 nm to 800 nm, and absorb at least light with a certain wavelength included in this wavelength range. The light absorption particles 22 preferably absorb at least part of the light with a wavelength of 550 nm to 650 nm. The light absorption particles 22 remove at least part of the light with a wavelength of 470 nm to 800 nm that is included in the light emitted from the GaN-based semiconductor particles 18 and that causes a reduction in the color purity, thereby increasing the purity of blue light to exit from the light emitting layer 21. Furthermore, it is possible to ensure a higher purity of blue light by the light absorption particles 22 removing at least part of the light with a wavelength of 550 nm to 650 nm that is the wavelength range of yellow to orange light. In order to achieve still higher color purity, the light absorption particles 22 preferably absorb all the light in the wavelength range of 550 nm to 650 nm, and more preferably absorb all the light in the wavelength range of 470 nm to 800 nm. Further, it is preferable to provide the light absorption particles 22 so that the transmittance (transmitted light/incident light) with respect to the light with a wavelength of 550 nm to 650 nm is 0.3 or less in the light emitting layer 21. With this light absorption particles 22, still higher color purity can be achieved by effectively removing yellow to orange light that is included in the light emitted from the GaN-based semiconductor particles 18. It should be noted that since the light emitting device of this embodiment is intended to obtain blue light, the light absorption particles 22 do not absorb blue light substantially, and even if absorbing it, the absorptivity is very low.

The light absorption particles 22 are formed using a material capable of absorbing the light in the above-mentioned wavelength range. For example, an iron blue pigment that is cobalt-aluminum-silicon oxide, ultramarine that is a silicate of aluminum and sodium, inorganic pigments such as cobalt aluminate, organic pigments such as copper phthalocyanine and indanthrone blue, nanoparticles of metals such as gold and silver, and semiconductor materials with a band gap of about 1.7 to 2.5 eV (for example, SiC, Se, AlP, AlAs, GaP, ZnSe, ZnTe, CdS, and CdSe) can be used for the formation. The light absorption particles 22 may include only one kind of material, or may include two or more kinds of materials.

The shape and size of the light absorption particles 22 are not particularly limited, as long as the light absorption particles 22 can be dispersed in the light emitting layer 21. In order to achieve a favorable dispersibility in the binder, the average particle size is desirably 1 μm or less. It should be noted that the average particle size of the light absorption particles 22 is calculated in the same manner as the average particle size of the GaN-based semiconductor particles 18.

It is desirable to adjust the content of the light absorption particles 22 in the light emitting layer 21 appropriately, depending on the type of the material to be used for the light absorption particles 22, and thus there is no particular limitation thereon. However, it may be adjusted, for example, to 20 to 70 mass % in order to achieve more effective light absorption.

### Embodiment 3

As a light emitting device according to Embodiment 3 of the present invention, an RGB full color light emitting device that employs a full color system is described. It should be noted that in this embodiment, the same parts as in the light emitting device of Embodiment 1 may be indicated with identical reference numerals and the same description is not repeated in some cases.

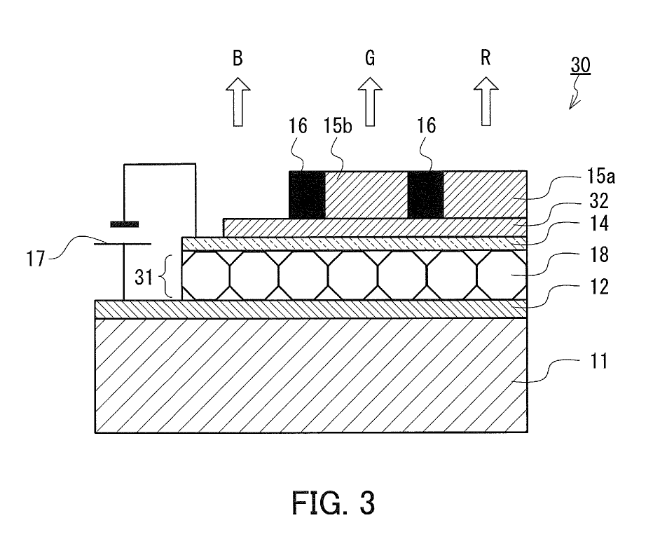

FIG. 3 is a sectional view illustrating a schematic configuration example of the light emitting device according to this embodiment. The light emitting device of this embodiment has the same configurations as in Embodiment 1 except that the configuration of the light emitting layer is different from that of the light emitting device of Embodiment 1, and a light absorption layer (light absorber) is provided on the light exit side with respect to the light emitting layer. Therefore, only the light emitting layer and the light absorption layer are described herein.

A light emitting layer 31 in a light emitting device 30 indicated in FIG. 3 includes the GaN-based semiconductor particles 18. Further, a light absorption layer 32 disposed between the transparent electrode 14 and the color conversion layers 15a and 15b is provided in the light emitting device 30. The light absorption layer 32 absorbs at least part of the light with a wavelength of 470 nm to 800 nm.

In the light emitting device 30, when a voltage is applied using the direct current power source 17, holes are injected into the light emitting layer 31 from the back electrode 12 that is connected to the positive electrode, and electrons are injected into the light emitting layer 31 from the transparent electrode 14 that is connected to the negative electrode. The electrons and the holes that have been injected into the light emitting layer 31 are injected into the GaN-based semiconductor particles 18 to recombine inside the particles 18. This recombination causes light emission. When the emitted light passes through the light absorption layer 32 disposed on the light exit side with respect to the light emitting layer 31, at least part of the light with a wavelength of 470 nm to 800 nm is absorbed by the light absorption layer 32. Accordingly, the light to exit from the light absorption layer 32 is blue light with high color purity after the removal of the light. The light that has passed through the light absorption layer 32 transmits through the color conversion layers 15a and 15b, so as to exit the light emitting device 30. The blue light is converted into red light or green light by passing through the color conversion layers 15a and 15b, so that light of each part of the RGB colors can be obtained.

It should be noted that a color filter may be provided over the color conversion layers 15a and 15b for the purpose of further improving the color purity, as is the case of Embodiment 1. Further, a protective film may be provided on the color conversion layers 15a and 15b, or on the color filter in the case of providing the color filter, for the purpose of preventing the deterioration of the device.

Further, although the black matrix 16 is provided to prevent colors from being mixed with each other in this embodiment, it also is possible to employ other configurations, for example, in which a separator is provided inside the light emitting layer 31 for each color pixel, or in which, in the case where a color filter is provided, a black matrix is provided for each color pixel of the color filter.

The components of the substrate 11, the electrodes (back electrode 12 and transparent electrode 14), the color conversion layers 15a and 15b and the GaN-based semiconductor particles 18 of the light emitting layer 31 in the light emitting device 30 respectively are the same as those in Embodiment 1, and thus the descriptions thereof are omitted in this embodiment.

<Light Emitting Layer>

The light emitting layer 31 at least includes the GaN-based semiconductor particles 18 that serve as a luminescent material. The light emitting layer 31 may further include a binder resin that allows the GaN-based semiconductor particles 18 to be dispersed therein, and a material intended to improve the injection performance of electrons or holes into the GaN-based semiconductor particles 18 (such as a hole transport material, an electron transport material, and the like). The specific examples of the hole transport material and the electron transport material are as described in Embodiment 1.

<Light Absorption Layer>

The light absorption layer 32 absorbs at least part of the light with a wavelength of 470 nm to 800 nm, and absorbs at least light with a certain wavelength included in this wavelength range. The light absorption layer 32 preferably absorbs at least part of the light with a wavelength of 550 nm to 650 nm. The light absorption layer 32 removes at least part of the light with a wavelength of 470 nm to 800 nm that is included in the light emitted from the GaN-based semiconductor particles 18 and that causes a reduction in the color purity, thereby increasing the purity of blue light to exit from the light emitting layer 31 via the light absorption layer 32. Furthermore, it is possible to ensure a higher purity of blue light by the light absorption layer 32 removing at least part of the light with a wavelength of 550 nm to 650 nm that is the wavelength range of yellow to orange light. In order to achieve still higher color purity, the light absorption layer 32 preferably absorbs all the light in the wavelength range of 550 nm to 650 nm, and more preferably absorbs all the light in the wavelength range of 470 nm to 800 nm. Further, it is preferable that the transmittance (transmitted light/incident light) with respect to the light with a wavelength of 550 nm to 650 nm is 0.3 or less in the light absorption layer 32. With this light absorption layer 32, still higher color purity can be achieved by effectively removing yellow to orange light that is included in the light emitted from the GaN-based semiconductor particles 18. It should be noted that since the light emitting device 30 in this embodiment is intended to obtain blue light, the light absorption layer 32 does not absorb blue light substantially, and even if absorbing it, the absorptivity is very low.

The light absorption layer 32 is formed using a material capable of absorbing the light in the above-mentioned wavelength range. For example, an iron blue pigment that is cobalt-aluminum-silicon oxide, ultramarine that is a silicate of aluminum and sodium, inorganic pigments such as cobalt aluminate, organic pigments such as copper phthalocyanine and indanthrone blue, nanoparticles of metals such as gold and silver, and semiconductor materials with a band gap of about 1.7 to 2.5 eV (for example, SiC, Se, AlP, AlAs, GaP, ZnSe, ZnTe, CdS, and CdSe) can be used for the formation. The light absorption layer 32 may include only one kind of material, or may include two or more kinds of materials. Further, it also is possible to produce the light absorption layer 32 using a multilayer interference film such as a silicon oxide/chromium-based film and a silicon oxide/titanium-based film. It is desirable to adjust the content of the above material to be contained in the light absorption layer 32 appropriately depending on the type of the material to be used, and thus there is no particular limitation thereon. However, it may be adjusted, for example, to 30 mass % or more in order to achieve more effective light absorption. Further, the light absorption layer 32 may be formed of only the above-mentioned material.

It is desirable to adjust the thickness of the light absorption layer 32 appropriately depending on the material to be used, and thus there is no particular limitation thereon. However, it may be adjusted, for example, to 2 to 500 nm.

In this embodiment, the light absorption layer 32 is disposed between the transparent electrode 14 that is disposed on the light exit side among a pair of electrodes, and the color conversion layers 15a and 15b. However, there is no limitation on the position. For example, in the case where the light absorption layer 32 has an electrical conductivity, it also is possible to dispose the light absorption layer 32 between the light emitting layer 31 and the transparent electrode 14 that is disposed on the light exit side among the pair of the electrodes. In this case, the light absorption layer 32 with electrical conductivity can be produced by adjusting the content of a material having low electrical resistivity, such as nanoparticles of metals.

The light absorption layer 32 can be produced by various methods such as vacuum evaporation, spin coating, ink jetting, and printing. In the case of using spin coating or ink jetting, it is desirable to use a binder resin, a solvent, a curing accelerator and the like appropriately in addition to the light absorption materials exemplified above, so as to facilitate the formation of the light absorption layer 22.

### Embodiment 4

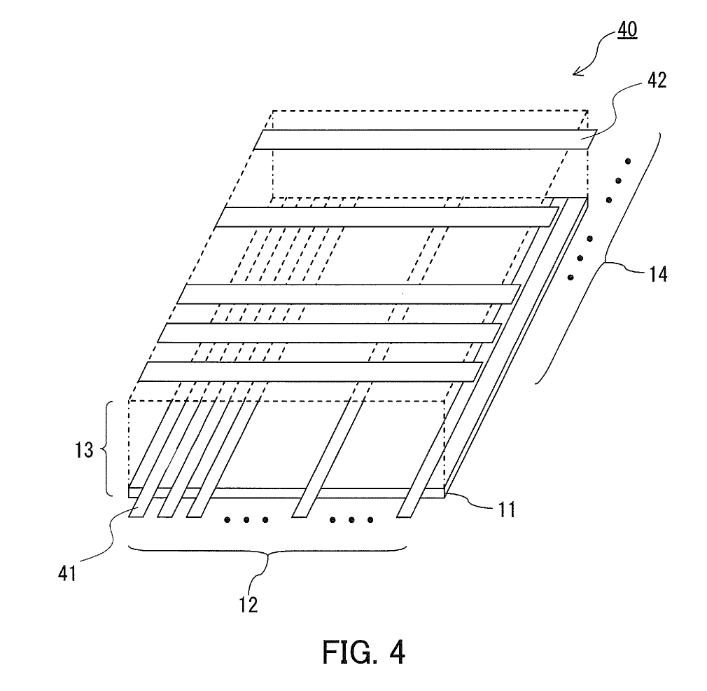

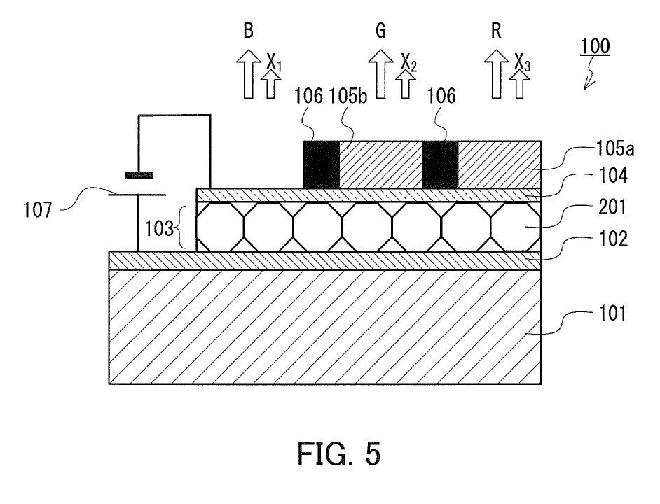

A configuration example of the display device according to Embodiment 4 of the present invention is described with reference to FIG. 4. A display device 40 according to this embodiment is provided with the light emitting device of the present invention, and is a passive matrix display using the light emitting device 10 described in Embodiment 1 (see FIG. 1). In order to illustrate the configuration of the display device 40 of this embodiment simply and easily, the color conversion layers 15a and 15b, and black matrix 16 (see FIG. 1) in the light emitting device 10 of Embodiment 1 are omitted in FIG. 4.

The display device 40 has a configuration in which the back electrode 12 and the transparent electrode 14 that are used in the light emitting device 10 indicated in FIG. 1 each are constituted by a plurality of stripe-shaped electrodes. The stripe-shaped electrodes 41 constituting the back electrode 12 are in a skewed relationship to the stripe-shaped electrodes 42 constituting the transparent electrode 14, and the projection of each stripe-shaped electrode 41 constituting the back electrode 12 and the projection of each stripe-shaped electrode 42 constituting the transparent electrode 14 on the light emitting surface (surface parallel to the light emitting layer 13) are crossed with each other (orthogonally, in this embodiment). In the display device 40, it is possible to cause light emission at a specific point (specific pixel) in the light emitting device by applying a voltage to each electrode selected respectively from the stripe-shaped electrodes 41 of the back electrodes 12 and the stripe-shaped electrodes 42 of the transparent electrodes 14.

Since the display device 40 uses the light emitting device of Embodiment 1, it is possible to achieve not only high brightness under low-voltage driving, but also full color display with high color reproducibility because each pixel emits the RGB light with high color purity. Although the passive matrix display is described as an example in this embodiment, the display device of the present invention is not limited thereto. For example, an active matrix display may be used. Further, a display device provided with the light emitting device 10 of Embodiment 1 is exemplified in this embodiment. However, it also is possible to employ a display device provided with the light emitting device 20 of Embodiment 2 or the light emitting device 30 of Embodiment 3, which brings about the same effects.

### EXAMPLE

Hereinafter, the present invention is described further in detail with reference to Examples and Comparative Examples. However, the present invention is not limited to the following examples as long as the invention is within the scope of the preset invention.

### Example 1

A light emitting device having the same structure as the light emitting device 10 shown in FIG. 1 was fabricated as a light emitting device of Example 1 by the following process.

(1) First, GaN particles were prepared as the GaN-based semiconductor particles 18. 0.18 g of Ga₂O₃ was allowed to react in an ammonia atmosphere at 1000° C. for 3 hours, thereby preparing a faintly yellow powder. This sample was GaN particles (average particle size: 1 μm) with high crystallinity, according to X-ray analysis. Further, a sharp peak at 430 nm and a weak broad peak centered at 600 nm were observed in the PL (Photo Luminescence) spectrum under irradiation with an ultraviolet lamp at 365 nm.

(2) Next, the light absorption film 19 was formed by depositing copper phthalocyanine (manufactured by Sigma-Aldrich Corporation at 99%) on the surface of the GaN particles prepared in (1) to the thickness of 50 nm by electron beam evaporation.

(3) Next, the light emitting device 10 as indicated in FIG. 1 was fabricated. First, the back electrode 12 was formed by depositing Pt on a glass substrate to the thickness of 200 nm by electron beam evaporation.

(4) Subsequently, the light emitting layer 13 was formed on the back electrode 12 as follows. The GaN particles with its surface covered with the light absorption film 19 formed in (2), a binder resin (ITO paste SC-115, manufactured by Sumitomo Metal Mining Co., Ltd.), and a tetraphenyl butadiene-based derivative (“P770”, manufactured by TAKASAGO INTERNATIONAL CORPORATION) as an organic hole transport material were prepared, and a paste was prepared by mixing the GaN particles, the binder resin, and the organic hole transport material at a mass ratio of 1:0.5:0.5. The light emitting layer 13 was fabricated by applying this paste onto the back electrode 12.

(5) Subsequently, the ITO was vapor deposited to the thickness of 200 nm on the light emitting layer 13, as the transparent electrode 14.

(6) Subsequently, the color conversion layers 15 were formed on the transparent electrode 14. SrS:Eu was vapor deposited on the red (R) region and SrGa₂S₄:Eu was vapor deposited on the green (G) region, each using a 200 nm-thick mask.

The light emitting device 10 of Example 1 was fabricated by the above steps (1) to (6).

Then, the transparent electrode 14 and the back electrode 12 of the light emitting device 10 were connected to a direct current power source (regulated DC power supply, manufactured by Kenwood Corporation), and a voltage of 10 V was applied thereto, so that the device was allowed to emit light. CIE chromaticity coordinate was determined using a UV-visible photodiode array spectrophotometer (MultiSpec-1500, manufactured by SHIMADZU CORPORATION) for each pixel. As a result, (0.6, 0.32) was obtained in the red (R) pixel portion, (0.25, 0.62) was obtained in the green (G) pixel portion, and (0.16, 0.05) was obtained in the blue (B) pixel portion.

### Example 2

A sample having the same structure as the light emitting device 20 shown in FIG. 2 was fabricated as a light emitting device of Example 2 by the following process.

(1) First, GaN particles were prepared as the GaN-based semiconductor particles 18. 0.18 g of Ga₂O₃ was allowed to react in an ammonia atmosphere at 1000° C. for 3 hours, thereby preparing a faintly yellow powder. This sample was GaN particles (average particle size: 1 μm) with high crystallinity, according to X-ray analysis. Further, a sharp peak at 430 nm and a weak broad peak centered at 600 nm were observed in the PL (Photo Luminescence) spectrum under irradiation with an ultraviolet lamp at 365 nm.

(2) Next, the light emitting device 20 as indicated in FIG. 2 was fabricated. First, the back electrode 12 was formed by depositing Pt on a glass substrate to the thickness of 200 nm by electron beam evaporation.

(3) Subsequently, the light emitting layer 21 was formed on the back electrode 12 as follows. The GaN particles prepared in (1), a binder resin (ITO paste SC-115, manufactured by Sumitomo Metal Mining Co., Ltd.), a tetraphenyl butadiene-based derivative (“P770”, manufactured by TAKASAGO INTERNATIONAL CORPORATION) as an organic hole transport material, and cobalt aluminate particles (product name: cobalt blue X with a particle size of 0.01 to 0.02 μm, manufactured by TOYO-GANRYO Inc.) as the light absorption particles 22 were prepared, and a paste was prepared by mixing the GaN particles, the binder resin, the organic hole transport material, and the light absorption particles 22 at a mass ratio of 1:0.5:0.5:0.1. The light emitting layer 21 was fabricated by applying this paste onto the back electrode 12.

(4) Subsequently, the ITO was vapor deposited to the thickness of 200 nm on the light emitting layer 21, as the transparent electrode 14.

(5) Subsequently, the color conversion layers 15 were formed on the transparent electrode 14. SrS:Eu was vapor deposited on the red (R) region and SrGa₂S₄:Eu was vapor deposited on the green (G) region, each using a 200 nm-thick mask.

The light emitting device 20 of Example 2 was fabricated by the above steps (1) to (5).

Then, the transparent electrode 14 and the back electrode 12 of the light emitting device 20 were connected to a direct current power source (regulated DC power supply, manufactured by Kenwood Corporation), and a voltage of 10 V was applied thereto, so that the device was allowed to emit light. CIE chromaticity coordinate was determined using a UV-visible photodiode array spectrophotometer (MultiSpec-1500, manufactured by SHIMADZU CORPORATION) for each pixel. As a result, (0.62, 0.31) was obtained in the red (R) pixel portion, (0.24, 0.62) was obtained in the green (G) pixel portion, and (0.15, 0.07) was obtained in the blue (B) pixel portion.

### Example 3

A sample having the same structure as the light emitting device 30 shown in FIG. 3 was fabricated as a light emitting device of Example 3 by the following process.

(1) First, GaN particles were prepared as the GaN-based semiconductor particles 18. 0.18 g of Ga₂O₃ was allowed to react in an ammonia atmosphere at 1000° C. for 3 hours, thereby preparing a faintly yellow powder. This sample was GaN particles (average particle size: 1 μm) with high crystallinity, according to X-ray analysis. Further, a sharp peak at 430 nm and a weak broad peak centered at 600 nm were observed in the PL (Photo Luminescence) spectrum under irradiation with an ultraviolet lamp at 365 nm.

(2) Next, the light emitting device 30 as indicated in FIG. 3 was fabricated. First, the back electrode 12 was formed by depositing Pt on a glass substrate to the thickness of 200 nm by electron beam evaporation.

(3) Subsequently, the light emitting layer 31 was formed on the back electrode 12 as follows. The GaN particles prepared in (1), a binder resin (ITO paste SC-115, manufactured by Sumitomo Metal Mining Co., Ltd.), and a tetraphenyl butadiene-based derivative (“P770”, manufactured by TAKASAGO INTERNATIONAL CORPORATION) as an organic hole transport material were prepared, and a paste was prepared by mixing the GaN particles, the binder resin, and the organic hole transport material at a mass ratio of 1:0.5:0.5. The light emitting layer 31 was fabricated by applying this paste onto the back electrode 12.

(4) Subsequently, the ITO was vapor deposited to the thickness of 200 nm on the light emitting layer 31, as the transparent electrode 14.

(5) Subsequently, the light absorption layer 32 was formed on the transparent electrode 14. An ultraviolet curable acrylic resin, CB-2000 (manufactured by FUJIFILM OLIN Co., Ltd.) that contains blue pigments dispersed therein as a light absorption material was applied thereto by spin coating, followed by drying at 90° C. for 10 minutes, which was irradiated with ultraviolet rays using a high-pressure mercury lamp. Subsequently, it was developed in a 1 wt % aqueous solution of sodium hydroxide for 20 seconds, and thereafter washed with water and sintered at 200° C. for 60 minutes. Thus, the light absorption layer 32 was formed.

(6) Subsequently, the color conversion layers 15 were formed on the light absorption layer 32. SrS:Eu was vapor deposited on the red (R) region and SrGa₂S₄:Eu was vapor deposited on the green (G) region, each using a 200 nm-thick mask.

The light emitting device 30 of Example 3 was fabricated by the above steps (1) to (6).

Then, the transparent electrode 14 and the back electrode 12 of the light emitting device 30 were connected to a direct current power source (regulated DC power supply, manufactured by Kenwood Corporation), and a voltage of 10 V was applied thereto, so that the device was allowed to emit light. CIE chromaticity coordinate was determined using a UV-visible photodiode array spectrophotometer (MultiSpec-1500, manufactured by SHIMADZU CORPORATION) for each pixel. As a result, (0.62, 0.32) was obtained in the red (R) pixel portion, (0.25, 0.61) was obtained in the green (G) pixel portion, and (0.16, 0.06) was obtained in the blue (B) pixel portion.

### Comparative Example

A comparative sample was fabricated in the same manner as in Example 1 except that the surface of the GaN particles was not covered with the light absorption film. With respect to this comparative sample, CIE chromaticity coordinate was determined by the same process as in Examples 1 to 3. As a result, (0.55, 0.4) was obtained in the R pixel portion, (0.35, 0.56) was obtained in the G pixel portion, and (0.25, 0.2) was obtained in the B pixel portion.

By comparing the resultant chromaticity coordinates of Examples 1 to 3 to those of Comparative Example, it was clearly confirmed that the color purity of each RGB pixel was improved more significantly in the light emitting devices of Examples provided with a light absorber (light absorption film, light absorption particles or light absorption layer) than in the light emitting device of Comparative Example.

### INDUSTRIAL APPLICABILITY

The light emitting device and display device of the present invention allow display with high brightness under low-voltage driving to be obtained as well as the RGB pixel with high color purity to be achieved. As a result, a full color display having excellent color reproducibility can be provided. Accordingly, the light emitting device and the display device of the present invention are useful particularly for high-definition display devices such as television.

1. A light emitting device comprising:
a light emitting layer including GaN-based semiconductor particles;
a pair of electrodes for injecting an electric current into the light emitting layer; and
a light absorber for absorbing at least part of light with a wavelength of 470 nm to 800 nm.

2. A light emitting device comprising:
a light emitting layer; and
a pair of electrodes for injecting an electric current into the light emitting layer, wherein
the light emitting layer includes GaN-based semiconductor particles, and
at least a part of a surface of each of the GaN-based semiconductor particles is provided with a light absorption film for absorbing at least part of the light with a wavelength of 470 nm to 800 nm.

3. The light emitting device according to claim 2, wherein
the light absorption film absorbs at least part of light with a wavelength of 550 nm to 650 nm.

4. The light emitting device according to claim 3, wherein
the light absorption film absorbs the light with a wavelength of 550 nm to 650 nm.

5. The light emitting device according to claim 4, wherein
the light emitting layer has a transmittance of 0.3 or less with respect to the light with a wavelength of 550 nm to 650 nm is 0.3 or less.

6. The light emitting device according to claim 2, wherein
the light absorption film has an electrical conductivity.

7. The light emitting device according to claim 2, further comprising:
a color conversion layer disposed on a light exit side with respect to the light emitting layer.

8. A display device comprising:
the light emitting device according to claim 2.

9. A light emitting device comprising:
a light emitting layer; and
a pair of electrodes for injecting an electric current into the light emitting layer, wherein
the light emitting layer includes GaN-based semiconductor particles and light absorption particles for absorbing at least part of light with a wavelength of 470 nm to 800 nm, and
the GaN-based semiconductor particles and the light absorption particles are dispersed in the light emitting layer.

10. The light emitting device according to claim 9, wherein
the light absorption particles absorb at least part of light with a wavelength of 550 nm to 650 nm.

11. The light emitting device according to claim 10, wherein
the light absorption particles absorb the light at a wavelength of 550 nm to 650 nm.

12. The light emitting device according to claim 11, wherein
the light emitting layer has a transmittance of 0.3 or less with respect to the light with a wavelength of 550 nm to 650 nm.

13. The light emitting device according to claim 9, wherein
the light absorption particles have an average particle size of 1 μm or less.

14. The light emitting device according to claim 9, further comprising:
a color conversion layer disposed on a light exit side with respect to the light emitting layer.

15. A display device comprising:
the light emitting device according to claim 9.

16. A light emitting device comprising:
a light emitting layer; and
a pair of electrodes for injecting an electric current into the light emitting layer, wherein
the light emitting layer includes GaN-based semiconductor particles,
the light emitting device further comprises a light absorption layer for absorbing at least part of light with a wavelength of 470 nm to 800 nm, and
the light absorption layer is disposed on a light exit side with respect to the light emitting layer.

17. The light emitting device according to claim 16, wherein
the light absorption layer absorbs at least part of light with a wavelength of 550 nm to 650 nm.

18. The light emitting device according to claim 17, wherein
the light absorption layer absorbs the light at a wavelength of 550 nm to 650 nm.

19. The light emitting device according to claim 18, wherein
the light absorption layer has a transmittance of 0.3 or less with respect to the light with a wavelength of 550 nm to 650 nm.

20. The light emitting device according to claim 16, wherein
the light absorption layer is disposed between the light emitting layer and an electrode disposed on the light exit side among the pair of the electrodes, and
the absorption layer has an electrical conductivity.

21. The light emitting device according to claim 16, further comprising:
a color conversion layer disposed on a light exit side with respect to the pair of the electrodes, wherein
the light absorption layer is disposed between an electrode disposed on the light exit side among the pair of the electrodes and the color conversion layer.

22. A display device comprising:
the light emitting device according to claim 16.
